(19) United States
(12) Patent Application Publication
(10) Pub. No.: US 2013/0298988 A1
(43) Pub. Date: Nov. 14, 2013

(54) SOLAR BATTERY AND METHOD OF MANUFACTURING SOLAR BATTERY

(71) Applicants: Koji Fukuda, Osaka-shi (JP); Tomoo Imataki, Osaka-shi (JP); Yasushi Sainoo, Osaka-shi (JP); Tomohiro Nishina, Osaka-shi (JP); Shinsuke Naito, Osaka-shi (JP); Akiko Tsunemi, Osaka-shi (JP); Tomoyo Shiraki, Osaka-shi (JP); Takayuki Yamada, Osaka-shi (JP); Masatomo Tanahashi, Osaka-shi (JP)

(72) Inventors: Koji Fukuda, Osaka-shi (JP); Tomoo Imataki, Osaka-shi (JP); Yasushi Sainoo, Osaka-shi (JP); Tomohiro Nishina, Osaka-shi (JP); Shinsuke Naito, Osaka-shi (JP); Akiko Tsunemi, Osaka-shi (JP); Tomoyo Shiraki, Osaka-shi (JP); Takayuki Yamada, Osaka-shi (JP); Masatomo Tanahashi, Osaka-shi (JP)

(73) Assignee: Sharp Kabushiki Kaisha, Osaka-shi, Osaka (JP)

(21) Appl. No.: 13/995,067

(22) PCT Filed: Dec. 14, 2011
(86) PCT No.: PCT/JP2011/078893

§ 371 Date: Jul. 31, 2013

(30) Foreign Application Priority Data
Dec. 17, 2010 (JP) 2010-281773

(51) Int. Cl. H01L 31/0224; H01L 31/18

(52) U.S. Cl. CPC H01L 31/022425; H01L 31/18
USPC 136/256; 438/98

(57) ABSTRACT

There is provided a solar battery, including: a solar cell including a porous electrode provided on at least one surface of a substrate; a conductive wire electrically connected to the porous electrode; and an adhesive material provided between the porous electrode and the conductive wire, wherein a part of the adhesive material penetrates into the porous electrode. There is also provided a method of manufacturing the solar battery.

### TECHNICAL FIELD

The present invention relates to a solar battery and a method of manufacturing a solar battery.

### BACKGROUND ART

In recent years, solar cells that convert solar energy into electrical energy are increasingly and rapidly expected as an energy source for the next generation in view of preservation of the global environment in particular. While there are a variety of types of solar cells such as those using compound semiconductor, organic material or the like, those using silicon crystal are currently mainstream.

A type of solar cell currently most manufactured and sold is a bifacial electrode type solar cell having an n electrode on a surface thereof receiving solar light (i.e., a light-receiving surface), and a p electrode on a surface thereof opposite to the light-receiving surface (i.e., a back surface).

A back electrode type solar cell having an n electrode and a p electrode only on a back surface of the solar cell, without having an electrode on a light-receiving surface of the solar cell, is also being developed.

A silver electrode formed by printing silver paste and then firing the silver paste is commonly used as the electrode of the solar cell (refer to, for example, paragraph [0038] of PTD 1 (Japanese Patent Laying-Open No. 2002-217434)).

The temperature in firing the silver paste is preferably set at a high temperature, because the strength of the silver electrode after firing can be ensured. However, exposure of a substrate to the high temperature in the process of manufacturing the solar cell may lead to reduction in power generation property of the solar cell.

A technique of connecting an interconnector formed by a copper lead and the like to the electrode in order to take out electric power generated by the solar cell to the outside is also commonly used (refer to, for example, paragraph [0033] of PTD 1 (Japanese Patent Laying-Open No. 2002-217434)).

A technique of connecting the electrode of the solar cell and the interconnector by a conductive adhesive material such as solder is also commonly used (refer to, for example, paragraph [0033] of PTD 1 (Japanese Patent Laying-Open No. 2002-217434)). Furthermore, lead-free solder using bismuth instead of lead in view of environmental friendliness is also common in recent years (refer to, for example, paragraph [0033] of PTD 1 (Japanese Patent Laying-Open No. 2002-217434)).

Tin forming the lead-free solder combines with silver easily. Therefore, when the silver electrode formed by firing the silver paste is immersed in a lead-free solder bath, there arises a so-called silver corrosion phenomenon in which silver of the silver electrode is taken into the lead-free solder bath. As a result, the silver electrode may become brittle or the silver electrode may peel off from the solar cell.

Accordingly, PTD 1 (Japanese Patent Laying-Open No. 2002-217434) discloses a technique of significantly delaying elution of silver contained in the silver electrode of the solar cell, by containing a certain amount of silver in the lead-free solder (refer to, for example, paragraph [0034] of PTD 1 (Japanese Patent Laying-Open No. 2002-217434)).

However, in the case of containing a certain amount of silver in the lead-free solder, the cost of the lead-free solder increases.

### CITATION LIST

### Patent Document

PTD 1: Japanese Patent Laying-Open No. 2002-217434

### SUMMARY OF INVENTION

### Technical Problem

As described above, in the technical field of the solar battery, it is requested to enhance the reliability of the electrode of the solar cell and thereby increase the long-term reliability of the solar battery.

In view of the above circumstances, an object of the present invention is to provide a solar battery with increased long-term reliability, and a method of manufacturing the solar battery.

### Solution to Problem

The present invention is directed to a solar battery, including: a solar cell including a substrate and a porous electrode provided on at least one surface of the substrate; a conductive wire electrically connected to the porous electrode; and an adhesive material provided between the porous electrode and the conductive wire, wherein a part of the adhesive material penetrates into the porous electrode.

Preferably, in the solar battery according to the present invention, a part of the adhesive material is in contact with a surface of the substrate located around the porous electrode, and the adhesive material is arranged across the inside and the outside of the porous electrode, the surface of the substrate located around the porous electrode, and the conductive wire.

Preferably, in the solar battery according to the present invention, the adhesive material that has penetrated into the porous electrode is in contact with the substrate.

Preferably, in the solar battery according to the present invention, the adhesive material includes a conductive adhesive material and an insulating adhesive material, and between an outer surface of the porous electrode and an outer surface of the conductive wire, the conductive adhesive material electrically connects the porous electrode and the conductive wire, and the insulating adhesive material penetrates into the porous electrode and mechanically connects the porous electrode and the conductive wire.

Furthermore, the present invention is directed to a method of manufacturing any one of the aforementioned solar batteries, including the steps of: placing the adhesive material on at least one of the porous electrode and the conductive wire; superimposing the porous electrode with the conductive wire; causing a part of the adhesive material to penetrate into the porous electrode; and curing the adhesive material, wherein the step of curing is a step performed after the step of causing a part of the adhesive material to penetrate.

Preferably, in the method of manufacturing the solar battery according to the present invention, the adhesive material includes a conductive adhesive material and an insulating adhesive material, and between an outer surface of the porous electrode and an outer surface of the conductive wire, the conductive adhesive material electrically connects the porous electrode and the conductive wire, and the insulating adhesive material mechanically connects the porous electrode and the conductive wire, and in the step of causing a part of the adhesive material to penetrate, the insulating adhesive material penetrates into the porous electrode before the conductive adhesive material melts.

### Advantageous Effects of Invention

According to the present invention, there can be provided a solar battery with increased long-term reliability, and a method of manufacturing the solar battery.

### BRIEF DESCRIPTION OF DRAWINGS

FIG. 1 is a schematic cross-sectional view of a solar battery in the present embodiment.

FIGS. 2(a) to (g) are schematic cross-sectional views illustrating an example of a method of manufacturing a back electrode type solar cell used in the present embodiment.

FIG. 3 is a schematic plan view of an example of a back surface of the back electrode type solar cell used in the present embodiment.

FIG. 4 is a schematic plan view of another example of the back surface of the back electrode type solar cell used in the present embodiment.

FIG. 5 is a schematic plan view of still another example of the back surface of the back electrode type solar cell used in the present embodiment.

FIG. 6 is a schematic plan view of a surface, on a wire placement side, of an example of an interconnection sheet used in the present embodiment.

FIGS. 7(a) to (d) are schematic cross-sectional views illustrating an example of a method of manufacturing the interconnection sheet used in the present embodiment.

FIGS. 8(a) to (d) are schematic cross-sectional views illustrating an example of a method of manufacturing a solar battery in the present embodiment.

FIGS. 9(a) and (b) are schematic enlarged cross-sectional views illustrating a part of a process of the example of the method of manufacturing the solar battery in the present embodiment.

FIG. 10 is a schematic cross-sectional view of an example of a configuration in which the solar battery in the present embodiment is sealed in a sealant.

### DESCRIPTION OF EMBODIMENTS

Embodiments of the present invention will be described hereinafter. In the drawings of the present invention, the same reference characters represent the same portions or the corresponding portions. It is needless to say that other steps may be included in between steps described below.

<Solar Battery>

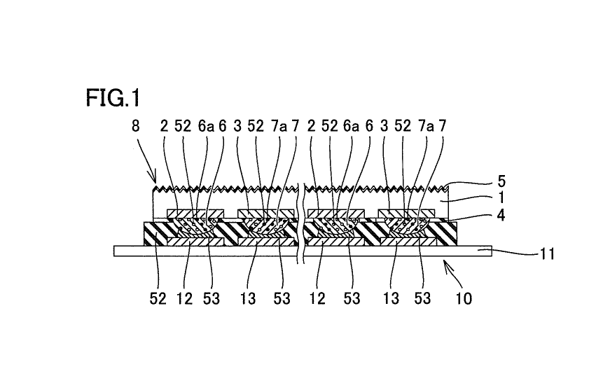

FIG. 1 shows a schematic cross-sectional view of a solar battery in the present embodiment, which is an example of a solar battery according to the present invention. As shown in FIG. 1, the solar battery in the present embodiment includes a back electrode type solar cell 8 and an interconnection sheet 10.

Back electrode type solar cell 8 has a substrate 1, and has a porous electrode for n type 6 provided on an n-type impurity diffused region 2 on a back surface of substrate 1, and a porous electrode for p type 7 provided on a p-type impurity diffused region 3. Porous electrode for n type 6 has a plurality of holes 6a extending from an outer surface to the inside thereof, and porous electrode for p type 7 has a plurality of holes 7a extending from an outer surface to the inside thereof. A passivation film 4 is formed on the regions on the back surface of substrate 1 other than the formation regions of porous electrode for n type 6 and porous electrode for p type 7. A textured structure and an anti-reflection film 5 are formed on a light-receiving surface of substrate 1.

Interconnection sheet 10 has an insulating base material 11, and has a wire for n type 12 and a wire for p type 13 provided on one surface of insulating base material 11. Wire for n type 12 is a wire corresponding to porous electrode for n type 6 and is provided to face porous electrode for n type 6. Wire for p type 13 is a wire corresponding to porous electrode for p type 7 and is provided to face porous electrode for p type 7.

A conductive adhesive material 53 is placed between the outer surface of porous electrode for n type 6 of back electrode type solar cell 8 and an outer surface of wire for n type 12 of interconnection sheet 10. Conductive adhesive material 53 electrically connects porous electrode for n type 6 and wire for n type 12.

Conductive adhesive material 53 is also placed between the outer surface of porous electrode for p type 7 of back electrode type solar cell 8 and an outer surface of wire for p type 13 of interconnection sheet 10. Conductive adhesive material 53 electrically connects porous electrode for p type 7 and wire for p type 13.

A part of an insulating adhesive material 52 penetrates into porous electrode for n type 6 from holes 6a of porous electrode for n type 6 of back electrode type solar cell 8, and insulating adhesive material 52 is integrally cured in a region extending from the inside of porous electrode for n type 6 to wire for n type 12, thereby mechanically connecting porous electrode for n type 6 and wire for n type 12.

A part of insulating adhesive material 52 penetrates into porous electrode for p type 7 from holes 7a of porous electrode for p type 7 of back electrode type solar cell 8, and insulating adhesive material 52 is integrally cured in a region extending from the inside of porous electrode for p type 7 to wire for p type 13, thereby mechanically connecting porous electrode for p type 7 and wire for p type 13.

Furthermore, insulating adhesive material 52 is placed in the regions between back electrode type solar cell 8 and interconnection sheet 10 other than the region between the porous electrode and the wire, and mechanically connects back electrode type solar cell 8 and interconnection sheet 10.

According to the solar battery in the present embodiment, insulating adhesive material 52 not only covers the outside of the porous electrode but also penetrates into the porous electrode. Therefore, the porous electrode is reinforced and the strength of the porous electrode is enhanced.

In addition, according to the solar battery in the present embodiment, insulating adhesive material 52 inside the porous electrode and insulating adhesive material 52 outside the porous electrode are integrally cured and strongly join back electrode type solar cell 8 and interconnection sheet 10. Therefore, peel-off of the porous electrode from back electrode type solar cell 8 can also be prevented.

For the above reasons, according to the solar battery in the present embodiment, the reliability of the porous electrode can be enhanced, and thus, the long-term reliability of the solar battery can be increased.

According to the solar battery in the present embodiment, insulating adhesive material 52 that has penetrated into the porous electrode is preferably in contact with substrate 1. In this case, a boundary portion between the porous electrode and substrate 1 can also be reinforced by insulating adhesive material 52 that has penetrated into the porous electrode. Therefore, the mechanical connection strength between the porous electrode and substrate 1 can be further increased, and the stability of electrical connection between the porous electrode and substrate 1 can be ensured. Accordingly, the reliability of the porous electrode can be further enhanced, and thus, the long-term reliability of the solar battery can be further increased.

<Back Electrode Type Solar Cell>

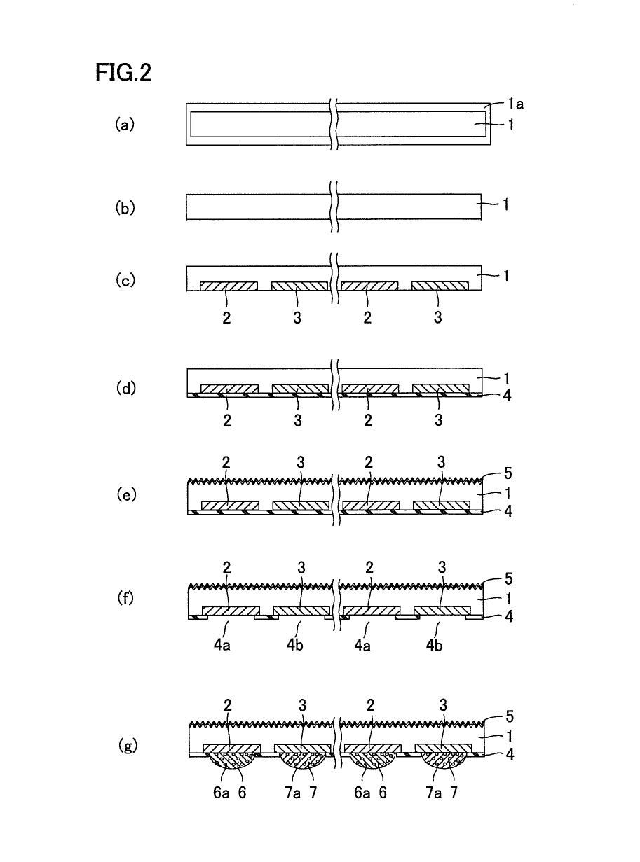

Back electrode type solar cell 8 manufactured as described below can, for example, be used as back electrode type solar cell 8. An example of a method of manufacturing back electrode type solar cell 8 used in the present embodiment will be described hereinafter with reference to schematic cross-sectional views in FIG. 2(a) to FIG. 2(g).

First, as shown in FIG. 2(a), by slicing from an ingot, for example, substrate 1 having a slice damage la on a surface thereof is prepared. A silicon substrate made of polycrystalline silicon, monocrystalline silicon or the like and having n-type conductivity or p-type conductivity can, for example, be used as substrate 1.

Next, as shown in FIG. 2(b), slice damage la on the surface of substrate 1 is removed. For example, when substrate 1 is formed of the aforementioned silicon substrate, slice damage la can be removed by etching the surface of the silicon substrate after slicing, with a mixed acid of hydrogen fluoride aqueous solution and nitric acid, an alkaline aqueous solution of sodium hydroxide or the like, and others.

The size and the shape of substrate 1 after removal of slice damage 1a are not particularly limited and the thickness of substrate 1 can be set to be, for example, 50 μm or more and 400 μm or less.

Next, as shown in FIG. 2(c), n-type impurity diffused region 2 and p-type impurity diffused region 3 are formed on the back surface of substrate 1. N-type impurity diffused region 2 can be formed, for example, by a vapor phase diffusion method and the like using a gas containing an n-type impurity, and p-type impurity diffused region 3 can be formed, for example, by a vapor phase diffusion method and the like using a gas containing a p-type impurity.

Each of n-type impurity diffused region 2 and p-type impurity diffused region 3 is formed in the shape of a strip extending toward the front surface side and/or the back surface side in the drawing sheet of FIG. 2. On the back surface of substrate 1, n-type impurity diffused region 2 and p-type impurity diffused region 3 are arranged alternately at a predetermined spacing.

N-type impurity diffused region 2 is not particularly limited as long as it is a region containing an n-type impurity and exhibiting n-type conductivity. An n-type impurity such as phosphorus can, for example, be used as the n-type impurity.

P-type impurity diffused region 3 is not particularly limited as long as it is a region containing a p-type impurity and exhibiting p-type conductivity. A p-type impurity such as boron or aluminum can, for example, be used as the p-type impurity.

A gas like POCl₃ containing the n-type impurity such as phosphorus can, for example, be used as the gas containing the n-type impurity. A gas like BBr₃ containing the p-type impurity such as boron can, for example, be used as the gas containing the p-type impurity.

Next, as shown in FIG. 2(d), passivation film 4 is formed on the back surface of substrate 1. Passivation film 4 can be formed by a method such as a thermal oxidation method or a plasma CVD (Chemical Vapor Deposition) method.

A silicon oxide film, a silicon nitride film, or a stack of the silicon oxide film and the silicon nitride film can, for example, be used as passivation film 4, although passivation film 4 is not limited thereto.

The thickness of passivation film 4 can be set to be, for example, 0.05 μm or more and 1 μm or less, and particularly preferably approximately 0.2 μm.

Next, as shown in FIG. 2(e), a concave-convex structure such as the textured structure is formed on the entire light-receiving surface of substrate 1, and thereafter, anti-reflection film 5 is formed on this concave-convex structure.

The textured structure can be formed, for example, by etching the light-receiving surface of substrate 1. For example, when substrate 1 is the silicon substrate, the textured structure can be formed, for example, by etching the light-receiving surface of substrate 1 with an etchant obtained by adding isopropyl alcohol to an alkaline aqueous solution such as sodium hydroxide or potassium hydroxide, and heating the liquid to, for example, 70° C. or higher and 80° C. or lower.

Anti-reflection film 5 can be formed, for example, by the plasma CVD method and the like. A silicon nitride film and the like can, for example, be used as anti-reflection film 5, although anti-reflection film 5 is not limited thereto.

Next, as shown in FIG. 2(f), a part of passivation film 4 on the back surface of substrate 1 is removed, thereby forming a contact hole 4a and a contact hole 4b. Contact hole 4a is formed to expose at least a part of a surface of n-type impurity diffused region 2, and contact hole 4b is formed to expose at least a part of a surface of p-type impurity diffused region 3.

Contact hole 4a and contact hole 4b can be formed, for example, by various methods such as a method of forming a resist pattern having openings at the portions corresponding to the formation sites of contact holes 4a and 4b on passivation film 4 by photolithography, and then etching away passivation film 4 through the openings of the resist pattern, or a method of applying etching paste to the portions of passivation film 4 corresponding to the formation sites of contact holes 4a and 4b, followed by heating to etch away passivation film 4.

Next, as shown in FIG. 2(g), porous electrode for n type 6 that is in contact with n-type impurity diffused region 2 through contact hole 4a and porous electrode for p type 7 that is in contact with p-type impurity diffused region 3 through contact hole 4b are formed. Back electrode type solar cell 8 is thus fabricated.

Porous electrode for n type 6 and porous electrode for p type 7 can be formed as described below, for example.

First, conventionally-known silver paste is screen-printed onto n-type impurity diffused region 2 exposed from contact hole 4a and p-type impurity diffused region 3 exposed from contact hole 4b.

Next, substrate 1 having the silver paste screen-printed thereon is heated. As a result, the silver paste is fired, and porous electrode for n type 6 and porous electrode for p type 7 that are porous silver electrodes can be formed. The temperature of heating the silver paste may be higher in some cases than the heating temperature in another process of manufacturing a solar cell, and lowering this temperature of heating the silver paste may lead to enhancement of the power generation efficiency of the solar cell. However, when the temperature of heating the silver paste is lowered, the joint strength of the porous silver electrodes after firing decreases and the porous silver electrodes become brittle. The present invention is effective when the porous silver electrodes after firing are brittle as described above.

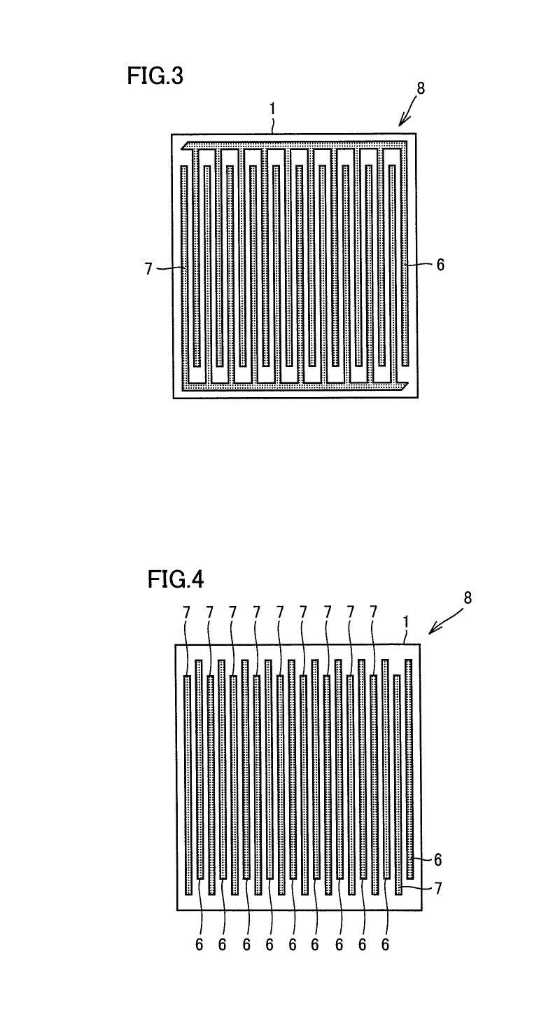

FIG. 3 shows a schematic plan view of an example of the back surface of back electrode type solar cell 8 used in the present embodiment. As shown in FIG. 3, each of porous electrode for n type 6 and porous electrode for p type 7 is formed in the shape of a comb, and porous electrode for n type 6 and porous electrode for p type 7 are arranged such that every single portion corresponding to a comb tooth of comb-shaped porous electrode for n type 6 and every single portion corresponding to a comb tooth of comb-shaped porous electrode for p type 7 interdigitate with each other. As a result, the portion corresponding to the comb tooth of comb-shaped porous electrode for n type 6 and the portion corresponding to the comb tooth of comb-shaped porous electrode for p type 7 are arranged alternately at a predetermined spacing.

FIG. 4 shows a schematic plan view of another example of the back surface of back electrode type solar cell 8 used in the present embodiment. As shown in FIG. 4, each of porous electrode for n type 6 and porous electrode for p type 7 is formed in the shape of a strip extending in the same direction (extending in a vertical direction in FIG. 4). On the back surface of substrate 1, porous electrode for n type 6 and porous electrode for p type 7 are arranged alternately in a direction orthogonal to the aforementioned extending direction.

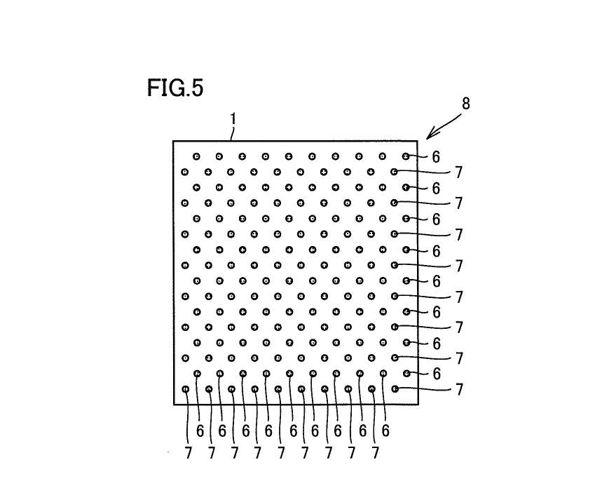

FIG. 5 shows a schematic plan view of sill another example of the back surface of back electrode type solar cell 8 used in the present embodiment. As shown in FIG. 5, each of porous electrode for n type 6 and porous electrode for p type 7 is formed in the shape of a dot. A line of dot-shaped porous electrodes for n type 6 (extending in a vertical direction in FIG. 5) and a line of dot-shaped porous electrodes for p type 7 (extending in the vertical direction in FIG. 5) are arranged alternately on the back surface of substrate 1.

The shape and the arrangement of porous electrode for n type 6 and porous electrode for p type 7 on the back surface of back electrode type solar cell 8 are not limited to the configurations shown in FIGS. 3 to 5. Any shapes and arrangements may be used as long as porous electrode for n type 6 and porous electrode for p type 7 can be electrically connected to wire for n type 12 and wire for p type 13 of interconnection sheet 10, respectively.

<Interconnection Sheet>

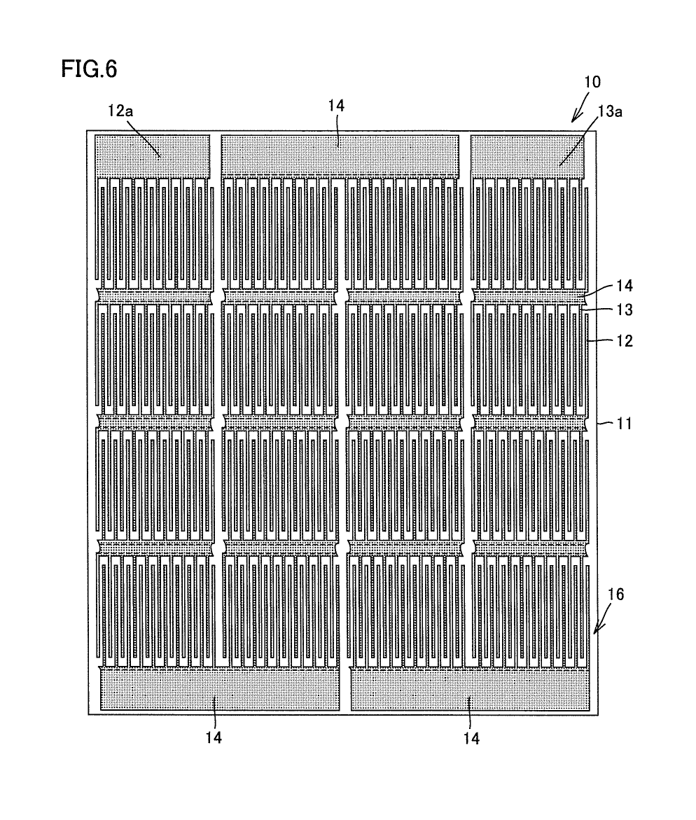

FIG. 6 shows a schematic plan view of a surface, on a wire placement side, of an example of the interconnection sheet used in the present embodiment. As shown in FIG. 6, interconnection sheet 10 has insulating base material 11, and a wire 16 including wire for n type 12, wire for p type 13 and a connecting wire 14 placed on a surface of insulating base material 11.

Wire for n type 12, wire for p type 13 and connecting wire 14 are conductive, and each of wire for n type 12 and wire for p type 13 has the shape of a comb including such a shape that a plurality of rectangles are arranged in a direction orthogonal to a longitudinal direction of the rectangles. On the other hand, connecting wire 14 has the shape of a strip. Other than a wire for n type 12a and a wire for p type 13a each located at an end of interconnection sheet 10, adjacent wires for n and p types 12 and 13 are electrically connected by connecting wire 14.

In interconnection sheet 10, wire for n type 12 and wire for p type 13 are arranged such that every single portion corresponding to a comb tooth (rectangle) of comb-shaped wire for n type 12 and every single portion corresponding to a comb tooth (rectangle) of comb-shaped wire for p type 13 interdigitate with each other. As a result, the portion corresponding to the comb tooth of comb-shaped wire for n type 12 and the portion corresponding to the comb tooth of comb-shaped wire for p type 13 are arranged alternately at a predetermined spacing.

A material of insulating base material 11 is not particularly limited as long as it is an electrically insulating material. A material including at least one type of resin selected from the group consisting of polyethylene terephthalate (PET), polyethylene naphthalate (PEN), polyphenylene sulfide (PPS), polyvinyl fluoride (PVF), and polyimide can, for example, be used.

The thickness of insulating base material 11 is not particularly limited and can be set to be, for example, 25 μm or more and 150 μm or less.

Insulating base material 11 may have a single layer structure formed of only one layer, or may have a multiple layer structure formed of two or more layers.

A material of wire 16 is not particularly limited as long as it is a conductive material. Metal and the like including at least one type of metal selected from the group consisting of copper, aluminum and silver can, for example, be used.

The thickness of wire 16 is not particularly limited, either, and can be set to be, for example, 10 μm or more and 50 μm or less.

It is needless to say that the shape of wire 16 is not limited to the aforementioned shape, either, and can be set as appropriate.

A conductive substance including at least one type of substance selected from the group consisting of nickel (Ni), gold (Au), platinum (Pt), palladium (Pd), silver (Ag), tin (Sn), SnPb solder, and ITO (Indium Tin Oxide) may, for example, be placed on at least a part of a surface of wire 16. In this case, electrical connection between wire 16 of interconnection sheet 10 and the electrode of back electrode type solar cell 8 described below tends to become excellent and the weather resistance of wire 16 tends to be enhanced.

At least a part of the surface of wire 16 may be subjected to surface treatment such as, for example, anti-rusting treatment and blackening treatment.

Wire 16 may also have a single layer structure formed of only one layer, or may have a multiple layer structure formed of two or more layers.

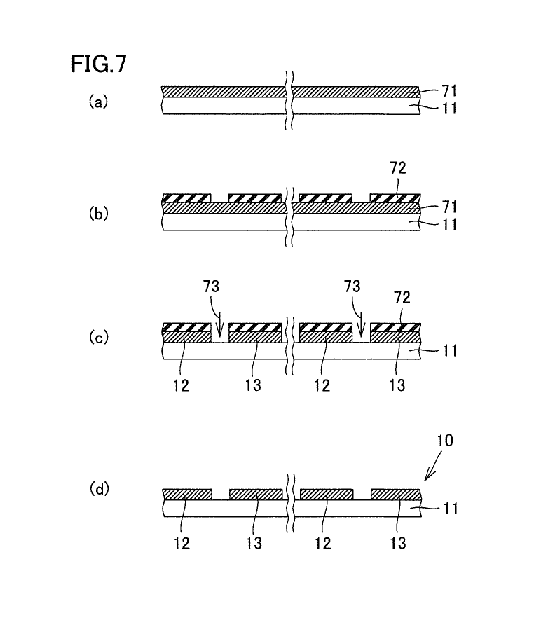

An example of a method of manufacturing interconnection sheet 10 used in the present embodiment will be described hereinafter with reference to schematic cross-sectional views in FIG. 7(a) to FIG. 7(d).

First, as shown in FIG. 7(a), a conductive layer 71 made of a conductive member is formed on the surface of insulating base material 11. A substrate made of a resin such as polyester, polyethylene naphthalate or polyimide can, for example, be used as insulating base material 11, although insulating base material 11 is not limited thereto.

The thickness of insulating base material 11 can be set to be, for example, 10 μm or more and 200 μm or less, and particularly preferably approximately 25 μm.

A layer made of metal such as copper can, for example, be used as conductive layer 71, although conductive layer 71 is not limited thereto.

Next, as shown in FIG. 7(b), a resist pattern 72 is formed on conductive layer 71 on the surface of insulating base material 11. Resist pattern 72 is formed in the shape having openings at the sites other than the formation sites of wire for n type 12, wire for p type 13 and connecting wire 14. A conventionally-known resist can, for example, be used as a resist forming resist pattern 72, and the resist can be applied by a method such as screen printing, dispenser application or inkjet application.

Next, as shown in FIG. 7(c), conductive layer 71 at the sites exposed from resist pattern 72 is removed in a direction shown by an arrow 73, thereby patterning conductive layer 71 to form wire for n type 12, wire for p type 13 and connecting wire 14 from the remaining portions of conductive layer 71.

Conductive layer 71 can be removed, for example, by wet etching and the like with an acid or alkaline solution.

Next, as shown in FIG. 7(d), resist pattern 72 is completely removed from surfaces of wire for n type 12, wire for p type 13 and connecting wire 14. Interconnection sheet 10 is thus fabricated.

<Method of Manufacturing Solar Battery>

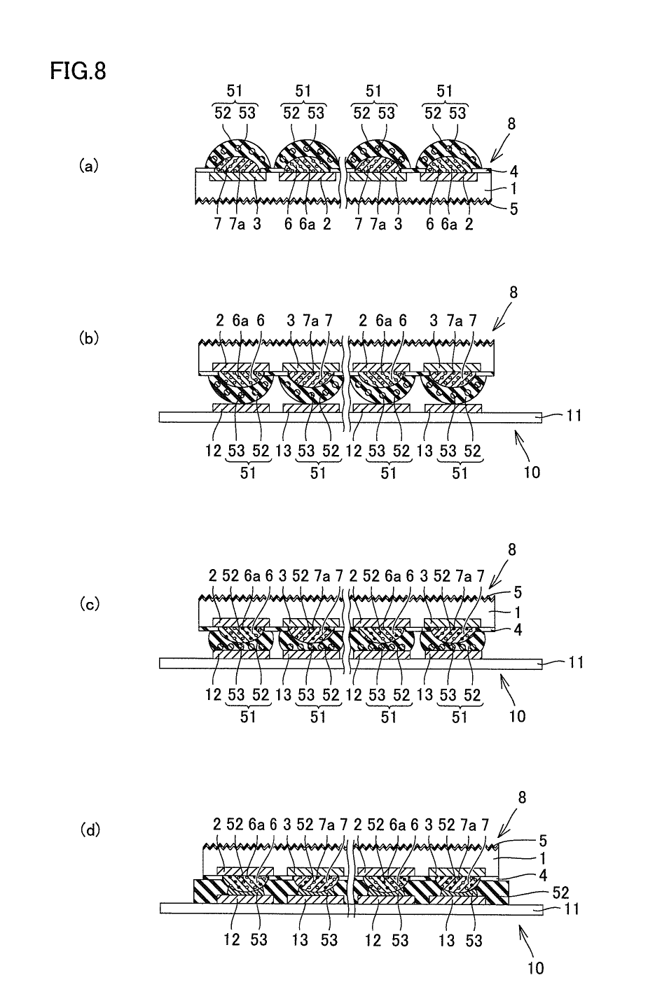

An example of a method of manufacturing a solar battery in the present embodiment will be described hereinafter with reference to schematic cross-sectional views in FIG. 8(a) to FIG. 8(d).

First, as shown in FIG. 8(a), a step of placing a solder resin 51 on a surface of each of porous electrode for n type 6 and porous electrode for p type 7 of back electrode type solar cell 8 is performed. Solder resin 51 includes insulating adhesive material 52 and conductive adhesive material 53, and has such a configuration that conductive adhesive material 53 is dispersed in insulating adhesive material 52. TCAP-5401-27 and the like manufactured by Tamura Kaken Corp. can, for example, be used as solder resin 51.

A thermosetting insulating resin and the like containing, as a resin component, at least one type of resin selected from the group consisting of an epoxy resin, an acrylic resin and a urethane resin can, for example, be used as insulating adhesive material 52.

Solder particles including at least one type of solder selected from the group consisting of Sn—Pb-based solder, Sn—Bi-based solder and Sn—Al-based solder, or solder particles obtained by adding other metal to the solder particles, and the like can, for example, be used as conductive adhesive material 53.

A method such as screen printing, dispenser application or inkjet application can, for example, be used as a method of placing solder resin 51, and use of screen printing is particularly preferable. When screen printing is used, solder resin 51 can be easily placed at low cost and in a short time.

In a below-described step of superimposing back electrode type solar cell 8 with interconnection sheet 10, it is preferable that conductive adhesive material 53 is in the form of a solid such as grain or powder. In addition, in the below-described step of superimposing back electrode type solar cell 8 with interconnection sheet 10, it is preferable that insulating adhesive material 52 is in the form of a liquid having appropriate liquidity. Such adhesive materials are used as conductive adhesive material 53 and insulating adhesive material 52, and thereby in a step described below, insulating adhesive material 52 can penetrate into the porous electrode before conductive adhesive material 53 in the form of a solid melts and penetrates into the porous electrode from the holes of the porous electrode. As a result, insulating adhesive material 52 can reinforce the porous electrode from inside and outside the porous electrode. Penetration of conductive adhesive material 53 can be suppressed by insulating adhesive material 52 that has penetrated into the porous electrode from the holes of the porous electrode. Therefore, even if the porous electrode is alloyed with the solder and becomes brittle, conductive adhesive material 53 is arranged to cover this portion and the shape can be maintained. Thus, the long-term reliability of the solar battery can be enhanced.

Next, as shown in FIG. 8(b), the step of superimposing back electrode type solar cell 8 with interconnection sheet 10 is performed.

The step of superimposing back electrode type solar cell 8 with interconnection sheet 10 can, for example, be performed such that porous electrode for n type 6 and porous electrode for p type 7 of back electrode type solar cell 8 are positioned to face wire for n type 12 and wire for p type 13 provided on insulating base material 11 of interconnection sheet 10, respectively. One back electrode type solar cell 8 may be superimposed on one interconnection sheet 10, or a plurality of back electrode type solar cells 8 may be superimposed on one interconnection sheet 10.

Next, as shown in FIG. 8(c), the step of causing a part of insulating adhesive material 52 to penetrate into porous electrode for n type 6 and porous electrode for p type 7 from holes 6a of porous electrode for n type 6 and holes 7a of porous electrode for p type 7 is performed. Thereafter, as shown in FIG. 8(d), a step of curing insulating adhesive material 52 is performed.

In the step of causing a part of insulating adhesive material 52 to penetrate into the porous electrode, insulating adhesive material 52 may be heated to a temperature lower than a temperature at which conductive adhesive material 53 melts. As a result, the viscosity of heated insulating adhesive material 52 decreases and the liquidity thereof increases, and thus, penetration of insulating adhesive material 52 into the porous electrode can be promoted. The step of curing insulating adhesive material 52 can, for example, be performed by further heating insulating adhesive material 52 and conductive adhesive material 53 between back electrode type solar cell 8 and interconnection sheet 10, subsequently to the immediately preceding step of causing a part of insulating adhesive material 52 to penetrate into the porous electrode.

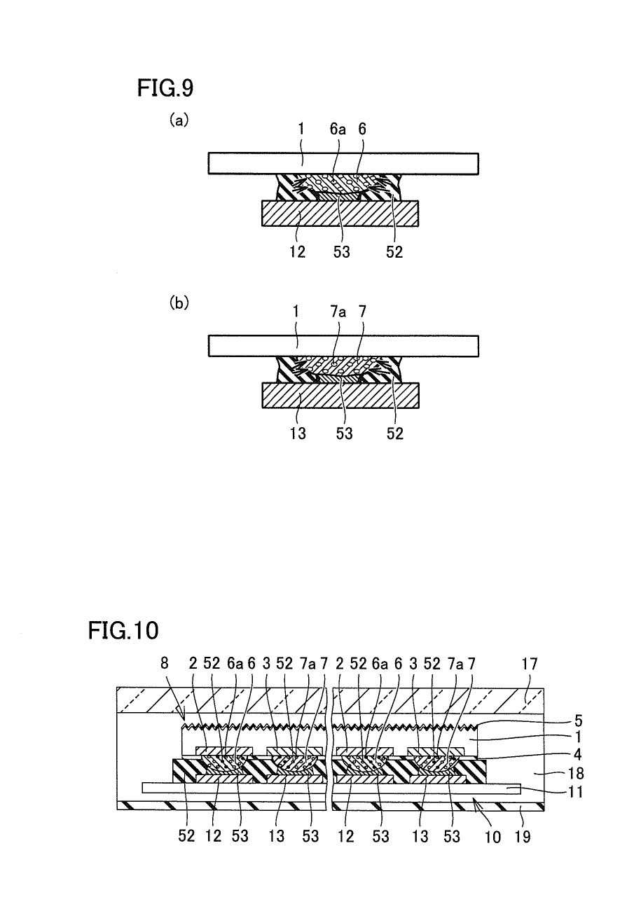

In this case, as shown in FIG. 9(a) and FIG. 9(b), for example, insulating adhesive material 52 penetrates into porous electrode for n type 6 and porous electrode for p type 7 from holes 6a of porous electrode for n type 6 and holes 7a of porous electrode for p type 7. Thereafter, conductive adhesive material 53 melts and spreads out to the outer surface of porous electrode for n type 6 and the outer surface of wire for n type 12 in a wet manner, and electrically connects porous electrode for n type 6 and wire for n type 12. Conductive adhesive material 53 also spreads out to the outer surface of porous electrode for p type 7 and the outer surface of wire for p type 13 in a wet manner, and electrically connects porous electrode for p type 7 and wire for p type 13. Then, by further heating, insulating adhesive material 52 is cured, with insulating adhesive material 52 having penetrated into the porous electrode from the holes in the outer surface of the porous electrode. By subsequent cooling, conductive adhesive material 53 is solidified.

Thus, by arranging conductive adhesive material 53 between the outer surface of porous electrode for n type 6 and the outer surface of wire for n type 12, porous electrode for n type 6 and wire for n type 12 can be electrically connected. By arranging conductive adhesive material 53 between the outer surface of porous electrode for p type 7 and the outer surface of wire for p type 13, porous electrode for p type 7 and wire for p type 13 can be electrically connected.

In addition, by causing a part of insulating adhesive material 52 to penetrate into porous electrode for n type 6, porous electrode for n type 6 and wire for n type 12 can be mechanically connected by insulating adhesive material 52. By causing a part of insulating adhesive material 52 to penetrate into porous electrode for p type 7, porous electrode for p type 7 and wire for p type 13 can be mechanically connected by insulating adhesive material 52.

In addition, insulating adhesive material 52 that has penetrated into porous electrode for n type 6 and/or insulating adhesive material 52 that has penetrated into porous electrode for p type 7 are preferably cured to be in contact with substrate 1. As a result, the boundary portion between the porous electrode and substrate 1 can also be reinforced. Therefore, the mechanical connection strength between the porous electrode and substrate 1 can be further increased, and the stability of electrical connection between the porous electrode and substrate 1 can be ensured. Accordingly, the reliability of the porous electrode can be further enhanced, and thus, the long-term reliability of the solar battery can be further increased.

By appropriately adjusting the conditions for forming the porous electrode and/or the conditions for forming insulating adhesive material 52, insulating adhesive material 52 can be cured, with insulating adhesive material 52 inside the porous electrode being in contact with substrate 1.

As described above, the solar battery in the present embodiment can be fabricated.

The case of placing solder resin 51 on the porous electrode of back electrode type solar cell 8 has been described above. Solder resin 51 may, however, be placed on the wire of interconnection sheet 10, or may be placed both on the porous electrode of back electrode type solar cell 8 and on the wire of interconnection sheet 10.

The case of using solder resin 51 has been described above. Other than solder resin 51, solder paste (having such a configuration that solder particles are dispersed in flux) and the like can also be used. In the case of using the solder paste, by separately arranging insulating adhesive material 52 between the porous electrode and the wire, insulating adhesive material 52 can penetrate into the porous electrode before the solder particles melt. The solder particles melt and spread out to the outer surface of the porous electrode and the wire in a wet manner, after insulating adhesive material 52 penetrates into the porous electrode. Therefore, electrical connection between the porous electrode and the wire by conductive adhesive material 53 can be ensured.

In the above, insulating adhesive material 52 and conductive adhesive material 53 may also be placed separately. Conductive adhesive material 53 may be brought into an easy-to-application and/or easy-to-printing state by mixing flux and/or solvent with the solder.

Placement of conductive adhesive material 53 is not essential. Even when conductive adhesive material 53 is not placed, the brittle porous electrode can be reinforced and mechanical connection between the porous electrode and the wire can be reinforced and ensured.

As shown in a schematic cross-sectional view in FIG. 10, the solar battery in the present embodiment fabricated as described above may be sealed in a sealant 18 located between a translucent substrate 17 and a protective base material 19.

The solar battery in the present embodiment is sealed in sealant 18, for example, by applying pressure to and heating sealant 18 between translucent substrate 17 and protective base material 19, with the solar battery being sandwiched between sealant 18 such as ethylene vinyl acetate (EVA) provided at translucent substrate 17 such as glass and sealant 18 such as EVA provided at protective base material 19 such as polyester film, and melting and curing sealant 18.

The case of using the back electrode type solar cell as the solar cell and using the wire as a conductive wire has been described above. However, the bifacial electrode type solar cell may be used as the solar cell and the conventionally-known interconnector may be used as the conductive wire.

It should be understood that the embodiments disclosed herein are illustrative and non-restrictive in every respect. The scope of the present invention is defined by the terms of the claims, rather than the description above, and is intended to include any modifications within the scope and meaning equivalent to the terms of the claims.

### INDUSTRIAL APPLICABILITY

The present invention can be used in a solar battery and a method of manufacturing the solar battery.

### REFERENCE SIGNS LIST

1 substrate; la slice damage; 2 n-type impurity diffused region; 3 p-type impurity diffused region; 4 passivation film; 5 anti-reflection film; 6 porous electrode for n type; 6a hole; 7 porous electrode for p type; 7a hole; 8 back electrode type solar cell; 10 interconnection sheet; 11 insulating base material; 12, 12a wire for n type; 13, 13a wire for p type; 14 connecting wire; 16 wire; 17 translucent substrate; 18 sealant; 19 protective base material; 52 insulating adhesive material; 53 conductive adhesive material; 71 conductive layer; 72 resist pattern; 73 arrow.

1. A solar battery, comprising:
a solar cell including a porous electrode provided on one surface of a substrate;
an interconnection sheet including a wire provided on one surface of an insulating base material; and
an insulating adhesive material provided between said solar cell and said interconnection sheet, wherein
a part of said insulating adhesive material penetrates into said porous electrode.

2. (canceled)

3. The solar battery according to claim 1, wherein
said insulating adhesive material that has penetrated into said porous electrode is in contact with said substrate.

4. The solar battery according to claim 1, wherein
said insulating adhesive material is obtained by separation from a mixture of a conductive adhesive material and said insulating adhesive material,
between an outer surface of said porous electrode and an outer surface of said wire, said conductive adhesive material electrically connects said porous electrode and said wire, and
said insulating adhesive material penetrates into said porous electrode and mechanically connects said solar cell and said interconnection sheet.

5. A method of manufacturing a solar battery including: a solar cell including a porous electrode provided on one surface of a substrate; and an interconnection sheet including a wire provided on one surface of an insulating base material, the method comprising the steps of:
placing an adhesive material including an insulating adhesive material and a conductive adhesive material on at least one of said porous electrode and said wire;
superimposing said porous electrode with said wire;
causing a part of said insulating adhesive material to penetrate into said porous electrode; and
curing said insulating adhesive material, with a part of said insulating adhesive material having penetrated into said porous electrode.

6. The method of manufacturing the solar battery according to claim 5, further comprising
melting said conductive adhesive material, with the part of said insulating adhesive material having penetrated into said porous electrode.
